(19) United States
(12) Patent Application Publication
(10) Pub. No.: US 2017/0222011 A1
(43) Pub. Date: Aug. 3, 2017

(54) Gate Metal Structure for Compound Semiconductor Devices

(71) Applicant: WIN Semiconductors Corp., Tao Yuan City (TW)

(72) Inventors: Chang-Hwang HUA, Tao Yuan City (TW); Kai-Sin CHO, Tao Yuan City (TW); Walter Tony WOHLMUTH, Tao Yuan City (TW)

(21) Appl. No.: 15/138,463

(22) Filed: Apr. 26, 2016

(30) Foreign Application Priority Data
Jan. 29, 2016 (TW) 105102891

(51) Int. Cl. H01L 29/47; H01L 29/205; H01L 23/535; H01L 29/778

(52) U.S. Cl. CPC H01L 29/475; H01L 29/7787; H01L 29/205; H01L 23/535

(57) ABSTRACT

An improved gate metal structure for compound semiconductor devices comprises sequentially a compound semiconductor substrate, a Schottky barrier layer, an insulating layer and a gate metal. The insulating layer has a gate recess. The surrounding and the bottom of the gate recess are defined by the insulating layer and the Schottky barrier layer respectively. The gate metal includes a contact layer formed on the insulating layer, covering the gate recess and contacted with the Schottky barrier layer at the bottom of the gate recess; a first diffusion barrier layer formed on the contact layer; a second diffusion barrier layer formed on the first diffusion barrier layer; and a conduct layer formed on the second diffusion barrier layer. Thereby the reliability of the compound semiconductor devices is enhanced.

### FIELD OF THE INVENTION

The present invention relates to an improved gate metal structure for compound semiconductor devices, especially to an improved gate metal structure having two diffusion barrier layers made of different materials for compound semiconductor devices.

### BACKGROUND OF THE INVENTION

Please refer to FIG. 2A, which is the sectional schematic view of an AlGaN/GaN high electron mobility transistor 2 of the conventional technology. The structure comprises a substrate 20, a GaN layer 210, an AlGaN layer 211, a gate electrode 22, a drain electrode 23, a source electrode 24 and an insulating layer 25. The substrate 20 is made of SiC. The GaN layer 210 is formed on the substrate 20. The AlGaN layer 211 is formed on the GaN layer 210. The insulating layer 25 is formed on the AlGaN layer 211. The insulating layer 25 is made of silicon nitride. The insulating layer 25 has a gate recess. The surrounding and the bottom of the gate recess are defined by the insulating layer 25 and the AlGaN layer 211 respectively. The gate electrode 22 is formed on the insulating layer 25 and covers the gate recess such that the gate electrode 22 is contacted with the AlGaN layer 211 at the bottom of the gate recess to form the Schottky contact. The drain electrode 23 and the source electrode 24 are formed respectively at the left and the right sides of the gate electrode 22 on the AlGaN layer 211. And the drain electrode 23 and the source electrode 24 form the ohmic contact with the AlGaN layer 211 respectively. Please also refer to FIG. 2B, which is the partial enlarged sectional schematic view of the gate electrode structure of an embodiment of FIG. 2A of an AlGaN/GaN high electron mobility transistor of the conventional technology. The gate electrode 22 comprises a contact layer 220, a diffusion barrier layer 221 and a conduct layer 222. The contact layer 220 is formed on the insulating layer 25 and covers the gate recess such that the contact layer 220 is contacted with the AlGaN layer 211 at the bottom of the gate recess to form the Schottky contact. In current embodiment, the contact layer 220 is made of Ni; the diffusion barrier layer 221 is formed on the contact layer 220, and the diffusion barrier layer 221 is made of Pt; the conduct layer 222 is formed on the diffusion barrier layer 221, and the conduct layer 222 is made of Au.

Due to the requirement of the reliability test, the AlGaN/GaN high electron mobility transistor must pass a reliability test at 300° C. for 6 hours and a reliability test at 110° C. for 500 hours. However after the reliability test at 300° C. for 6 hours, there are always some samples of the AlGaN/GaN high electron mobility transistor of the conventional technology as shown in FIG. 2A (the gate electrode structure formed by Ni, Pt and Au three metal layers, as shown in FIG. 2B) fail to fulfill the standard of the reliability test. Applicant analyzes these samples of devices which fail to pass the reliability testing. Please refer to FIG. 2C˜FIG. 2F, wherein FIG. 2C is the SEM image of an embodiment of an AlGaN/GaN high electron mobility transistor of the conventional technology after the reliability test at 300° C. for 6 hours; FIG. 2D˜FIG. 2F are the partial enlarged views of FIG. 2C respectively. After the reliability test at 300° C. for 6 hours, the gate electrode structure of the device generated some void defects. First of all, in FIG. 2F, the contact layer 220 (Ni) generated some void defects at the surrounding of the gate recess. While in FIG. 2D and FIG. 2E, the contact layer 220 (Ni) generated some void defects not only at the surrounding of the gate recess, but also at the bottom of the gate recess and on the top of insulating layer 25 (silicon nitride). As a result, the adhesion strength between Ni (the contact layer 220) and AlGaN is reduced, which may affect the reliability of the AlGaN/GaN high electron mobility transistor devices and may also affect many of the electrical characteristics of the devices.

Please refer to FIG. 2G which is the partial enlarged sectional schematic view of the gate electrode structure of another embodiment of FIG. 2A of an AlGaN/GaN high electron mobility transistor of the conventional technology. The gate electrode structure is mostly similar to the structure of the embodiment shown in FIG. 2B, except that the diffusion barrier layer 221 is made of Pd. Thus, the gate electrode is formed by Ni, Pd and Au three metal layers. Similarly, after the reliability test at 300° C. for 6 hours, there are always some samples of the AlGaN/GaN high electron mobility transistor of the conventional technology as shown in FIG. 2A (the gate electrode structure formed by Ni, Pd and Au three metal layers, as shown in FIG. 2G) fail to fulfill the standard of the reliability test. Applicant analyzes these samples of devices which fail to pass the reliability testing. Please also refer to FIG. 2H˜FIG. 2K, wherein FIG. 2H is the SEM image of another embodiment of an AlGaN/GaN high electron mobility transistor of the conventional technology after the reliability test at 300° C. for 5 minutes; FIG. 2I˜FIG. 2K are the partial enlarged views of FIG. 2H respectively. After the reliability test at 300° C. for 5 minutes, the gate electrode structure has been some changes. In some area, Au has started diffusing into Pd (the diffusion barrier layer 221). Please also refer to FIG. 2L˜FIG. 2O, wherein FIG. 2L is the SEM image of another embodiment of an AlGaN/GaN high electron mobility transistor of the conventional technology after the reliability test at 300° C. for 6 hours; FIG. 2M˜FIG. 2O are the partial enlarged views of FIG. 2L respectively. After the reliability test at 300° C. for 6 hours, the change of the gate electrode structure is tremendous. Au is not only diffusing through Pd (the diffusion barrier layer 221), but also diffusing into Ni (the contact layer 220). As a result, it may affect the reliability of the AlGaN/GaN high electron mobility transistor devices and may also affect many of the electrical characteristics of the devices.

Accordingly, applicant has developed a new design which may avoid the above mentioned drawbacks, may significantly enhance the performance of the devices and may take into account economic considerations. Therefore, the present invention then has been invented.

### SUMMARY OF THE INVENTION

From the results of the reliability tests to the conventional technology devices which use Pt or Pd as the material of the diffusion barrier layer, it seems that Pt or Pd these two kinds of metals are not suitable as the material of the diffusion barrier layer. However applicant observes from the phase diagram of the Au—Pt binary alloy, Au and Pt have excellent miscibility at 300° C. (or less). Hence, in the embodiment shown in FIG. 2B, at 300° C. (or less), the integrity of the interface between Au metal layer and Pt metal layer may be preserved; therefore, the cracks and peeling on the interface may be prevented. Therefore Au could not diffuse through Pt into Ni. In contrast, from the phase diagram of the Pt—Ni binary alloy, Pt and Ni have poor miscibility at 300° C. (or less). Therefore, it results in the phenomenon of void defects as shown in FIG. 2D˜FIG. 2F. Furthermore, in the embodiment shown in FIG. 2G, from the phase diagram of the Au—Pd binary alloy, even though Au and Pd have excellent miscibility at 300° C., Au and Pd have poor miscibility within the temperature range from about room temperature to 100° C. Therefore, when being heated up from room temperature to 300° C., it will go through the temperature range (from about room temperature to 100° C.) where Au and Pd have poor miscibility. Thus, after the reliability test at 300° C. for 5 minutes, Au has started diffusing into Pd as shown in FIG. 2H˜FIG. 2K. And then after the reliability test at 300° C. for 6 hours, Au has diffused through Pd, and also diffused into Ni.

In order to solve the problems mentioned the above, to preserve the stability of the characteristics of the devices after reliability testing, to achieve the effect of enhancing the reliability of the compound semiconductor devices, and to fulfill the standard of the reliability test, the present invention provides an improved gate metal structure for compound semiconductor devices which comprises a compound semiconductor substrate; a Schottky barrier layer formed on the compound semiconductor substrate; an insulating layer formed on the Schottky barrier layer, wherein the insulating layer has a gate recess, the surrounding and the bottom of the gate recess are defined by the insulating layer and the Schottky barrier layer respectively; and a gate metal including a contact layer, a first diffusion barrier layer, a second diffusion barrier layer and a conduct layer, wherein the contact layer is formed on the insulating layer and covers the gate recess, the contact layer contacts with the Schottky barrier layer at the bottom of the gate recess, the first diffusion barrier layer is formed on the contact layer, the second diffusion barrier layer is formed on the first diffusion barrier layer, and the conduct layer is formed on the second diffusion barrier layer, thereby the reliability of the compound semiconductor devices is enhanced.

In an embodiment of the improved gate metal structure for compound semiconductor devices, wherein the second diffusion barrier layer is made of Pt.

In an embodiment of the improved gate metal structure for compound semiconductor devices, wherein the second diffusion barrier layer is made of at least one material selected from the group consisting of Rh, Ta, Hf, Zr and Nb. Similarly, Rh, Ta, Hf, Zr or Nb may be substituted for Pt as the material of the second diffusion barrier layer and may also play the same effect.

In an embodiment of the improved gate metal structure for compound semiconductor devices, wherein the material of the second diffusion barrier layer is non-oxidized.

In an embodiment of the improved gate metal structure for compound semiconductor devices, wherein a thickness of the second diffusion barrier layer is greater than or equal to 10 Å and smaller than 500 Å.

In an embodiment of the improved gate metal structure for compound semiconductor devices, wherein the first diffusion barrier layer is made of Pd.

In an embodiment of the improved gate metal structure for compound semiconductor devices, wherein a thickness of the first diffusion barrier layer is greater than or equal to 10 Å and smaller than 500 Å.

In an embodiment of the improved gate metal structure for compound semiconductor devices, wherein the contact layer is made of Ni.

In an embodiment of the improved gate metal structure for compound semiconductor devices, wherein a thickness of the contact layer is greater than or equal to 10 Å and smaller than 500 Å.

In an embodiment of the improved gate metal structure for compound semiconductor devices, wherein the conduct layer is made of Au.

In an embodiment of the improved gate metal structure for compound semiconductor devices, wherein a thickness of the conduct layer is greater than or equal to 50 Å and smaller than 6000 Å.

In an embodiment of the improved gate metal structure for compound semiconductor devices, wherein the insulating layer is made of silicon nitride.

In an embodiment of the improved gate metal structure for compound semiconductor devices, wherein the compound semiconductor substrate is made of one material selected from the group consisting of GaAs, sapphire, InP, GaP, SiC and GaN.

In an embodiment of the improved gate metal structure for compound semiconductor devices, further comprising a protection layer formed on the conduct layer of the gate metal.

In an embodiment of the improved gate metal structure for compound semiconductor devices, wherein the protection layer is made of Ti.

In an embodiment of the improved gate metal structure for compound semiconductor devices, wherein the Schottky barrier layer includes a GaN sub-layer and an AlGaN sub-layer, the GaN sub-layer is formed on the compound semiconductor substrate, the AlGaN sub-layer is formed on the GaN sub-layer.

In an embodiment of the improved gate metal structure for compound semiconductor devices, wherein the contact layer is made of Ni; the first diffusion barrier layer is made of Pd; the second diffusion barrier layer is made of at least one material selected from the group consisting of Pt, Rh, Ta, Hf, Zr and Nb; and the conduct layer is made of Au.

For further understanding the characteristics and effects of the present invention, some preferred embodiments referred to drawings are in detail described as follows.

### BRIEF DESCRIPTION OF DRAWINGS

FIG. 1A is the sectional schematic view of an embodiment of an improved gate metal structure for compound semiconductor devices of the present invention.

FIG. 1B is the partial enlarged sectional schematic view of the gate electrode structure of an embodiment of an improved gate metal structure for compound semiconductor devices of the present invention.

FIG. 1C is the partial enlarged sectional schematic view of the gate electrode structure of another embodiment of an improved gate metal structure for compound semiconductor devices of the present invention.

FIG. 1D is the SEM image of an improved gate metal structure for compound semiconductor devices of the present invention after the reliability test at 300° C. for 6 hours.

FIG. 1E˜FIG. 1G are the partial enlarged views of FIG. 1D respectively.

FIG. 1H is the normalized drain saturation current at zero gate voltage (Idss) measurement result of an improved gate metal structure for compound semiconductor devices of the present invention after the reliability test at 110° C. for 500 hours.

FIG. 1I is the normalized zero bias threshold voltage (Vto) measurement result of an improved gate metal structure for compound semiconductor devices of the present invention after the reliability test at 110° C. for 500 hours.

FIG. 1J is the normalized ON-Resistance (Ron) measurement result of an improved gate metal structure for compound semiconductor devices of the present invention after the reliability test at 110° C. for 500 hours.

FIG. 2A is the sectional schematic view of an AlGaN/GaN high electron mobility transistor of the conventional technology.

FIG. 2B is the partial enlarged sectional schematic view of the gate electrode structure of an embodiment of FIG. 2A of an AlGaN/GaN high electron mobility transistor of the conventional technology.

FIG. 2C is the SEM image of an embodiment of an AlGaN/GaN high electron mobility transistor of the conventional technology after the reliability test at 300° C. for 6 hours.

FIG. 2D˜FIG. 2F are the partial enlarged views of FIG. 2C respectively.

FIG. 2G is the partial enlarged sectional schematic view of the gate electrode structure of another embodiment of FIG. 2A of an AlGaN/GaN high electron mobility transistor of the conventional technology.

FIG. 2H is the SEM image of another embodiment of an AlGaN/GaN high electron mobility transistor of the conventional technology after the reliability test at 300° C. for 5 minutes.

FIG. 2I˜FIG. 2K are the partial enlarged views of FIG. 2H respectively.

FIG. 2L is the SEM image of another embodiment of an AlGaN/GaN high electron mobility transistor of the conventional technology after the reliability test at 300° C. for 6 hours.

FIG. 2M˜FIG. 2O are the partial enlarged views of FIG. 2L respectively.

### DETAILED DESCRIPTIONS OF PREFERRED EMBODIMENTS

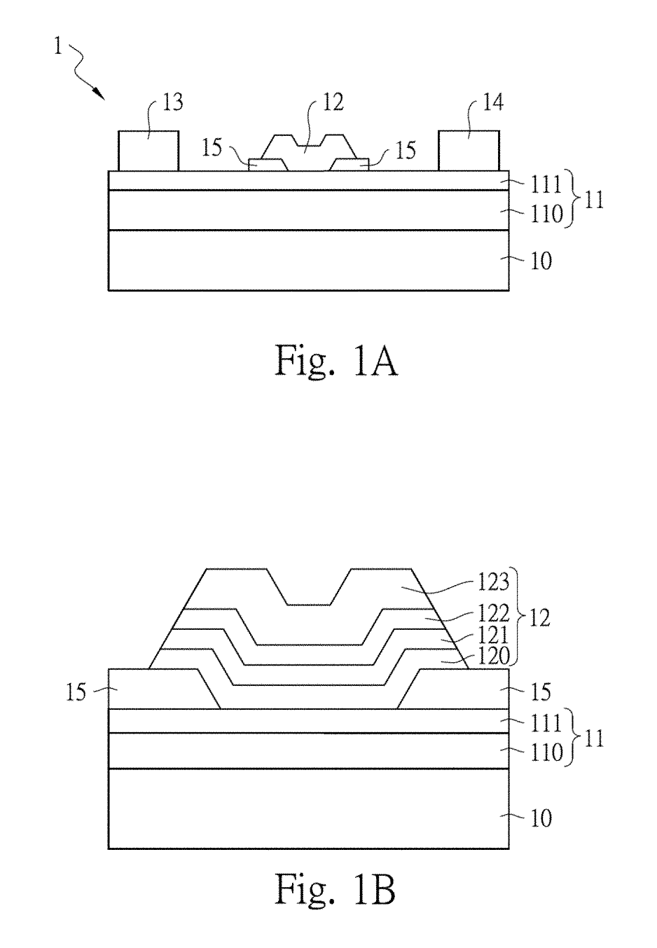

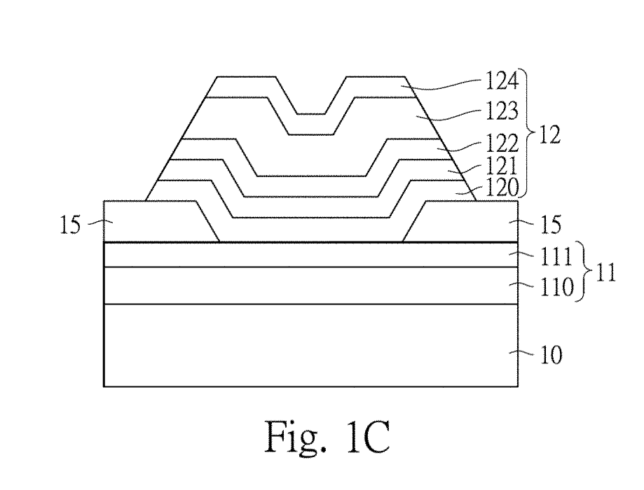

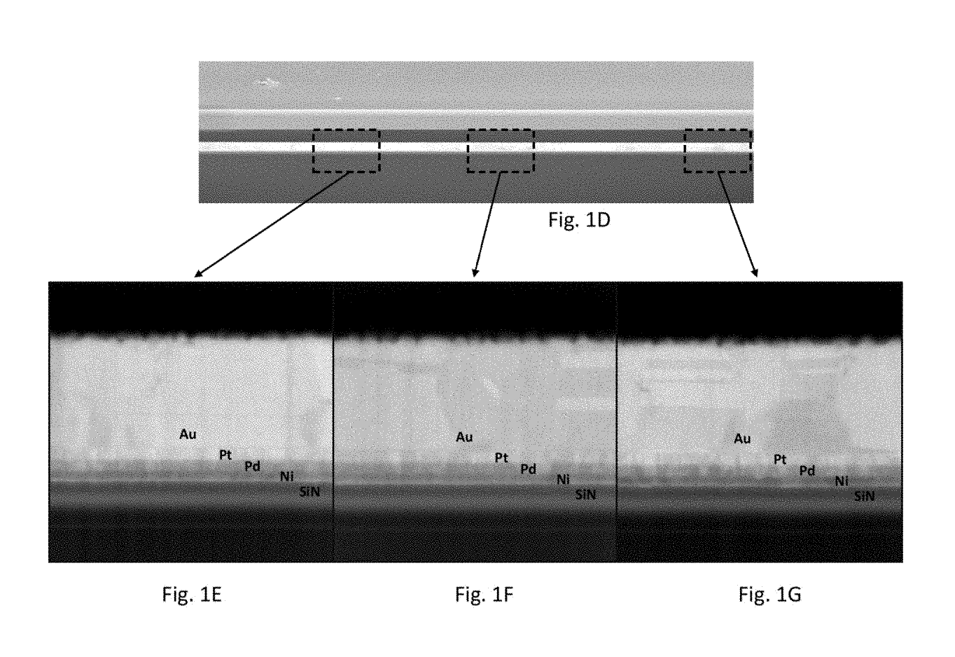

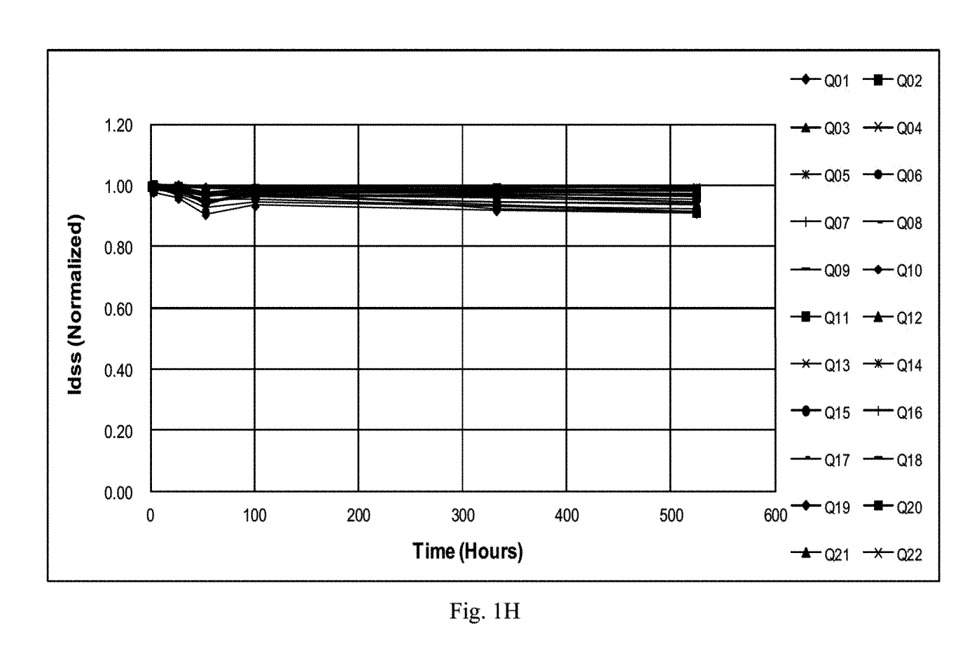

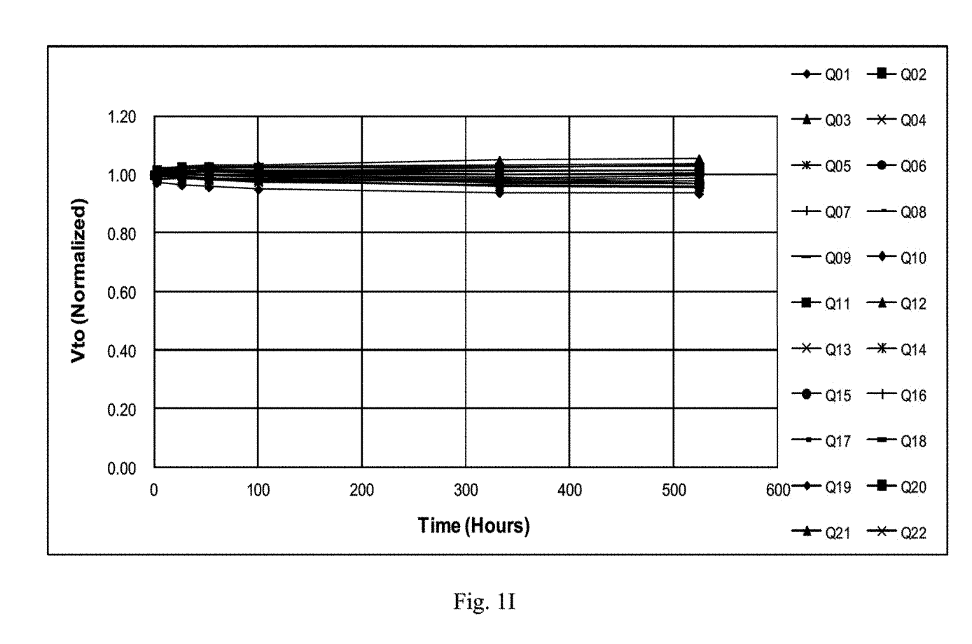

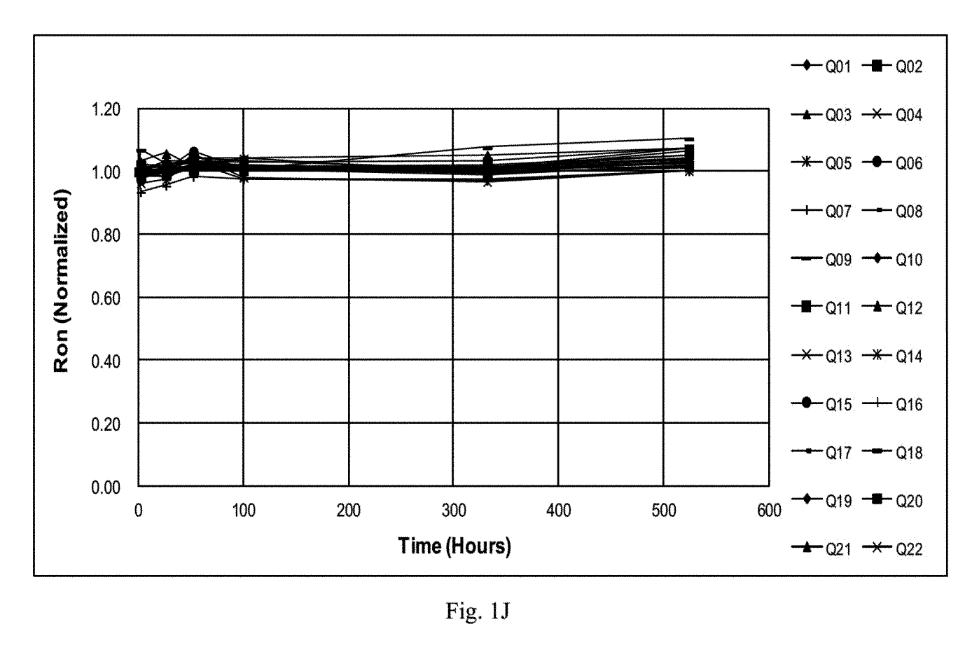

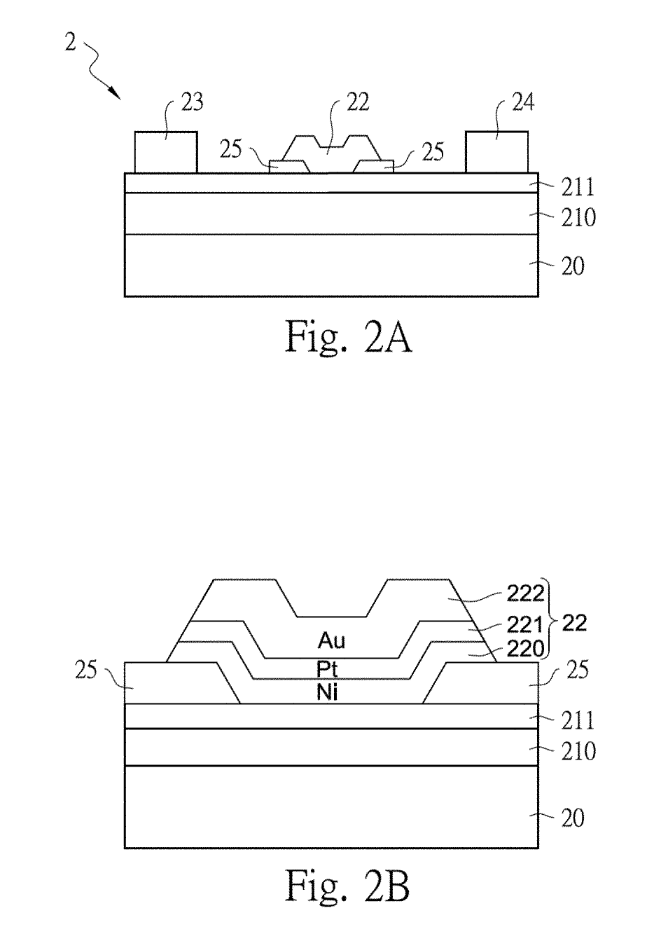

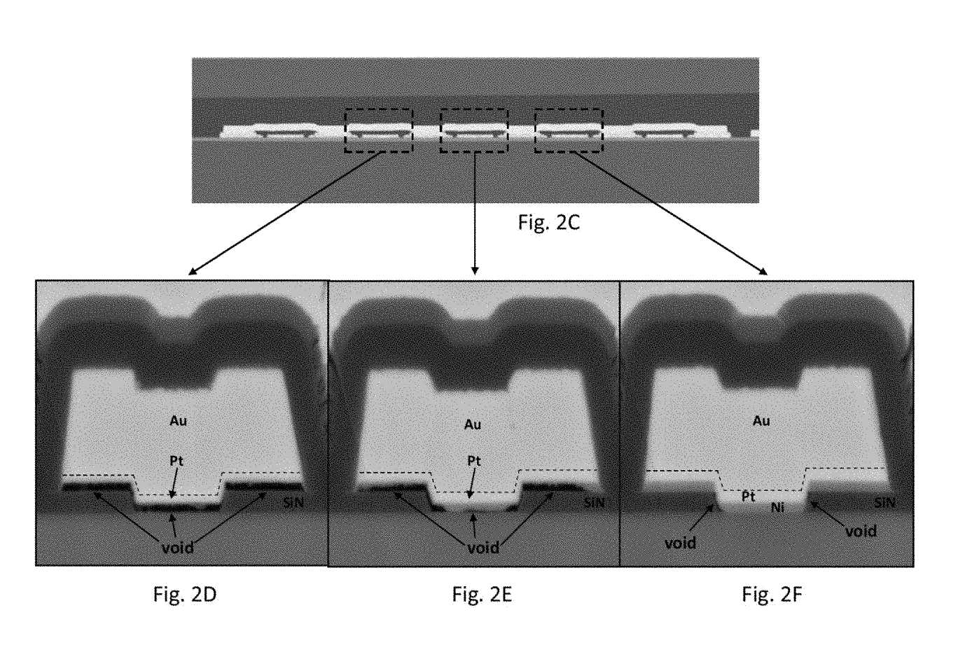

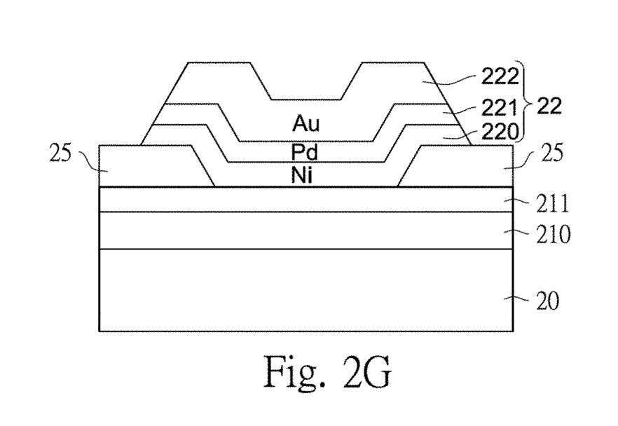

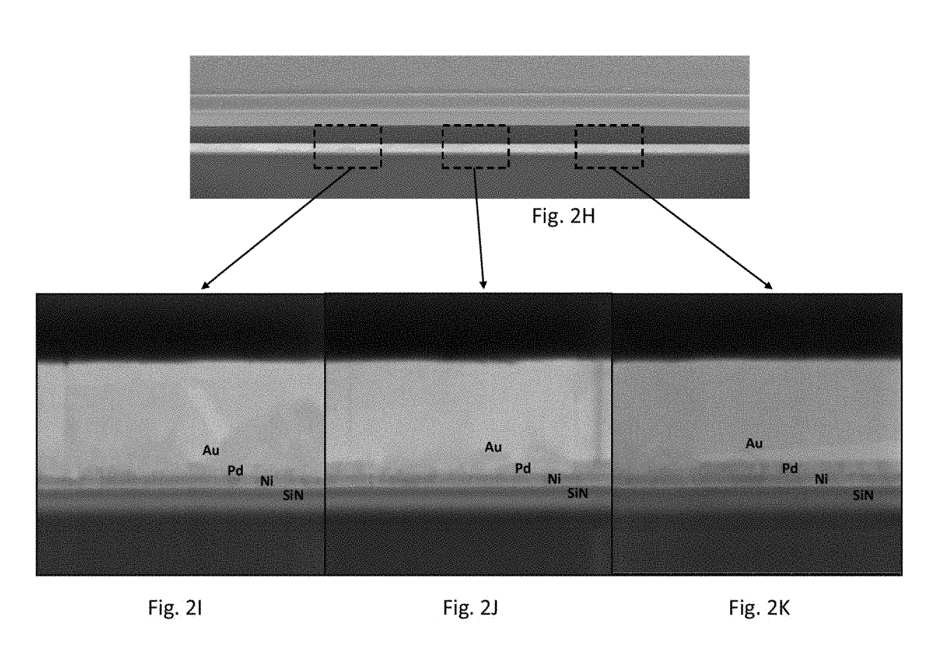

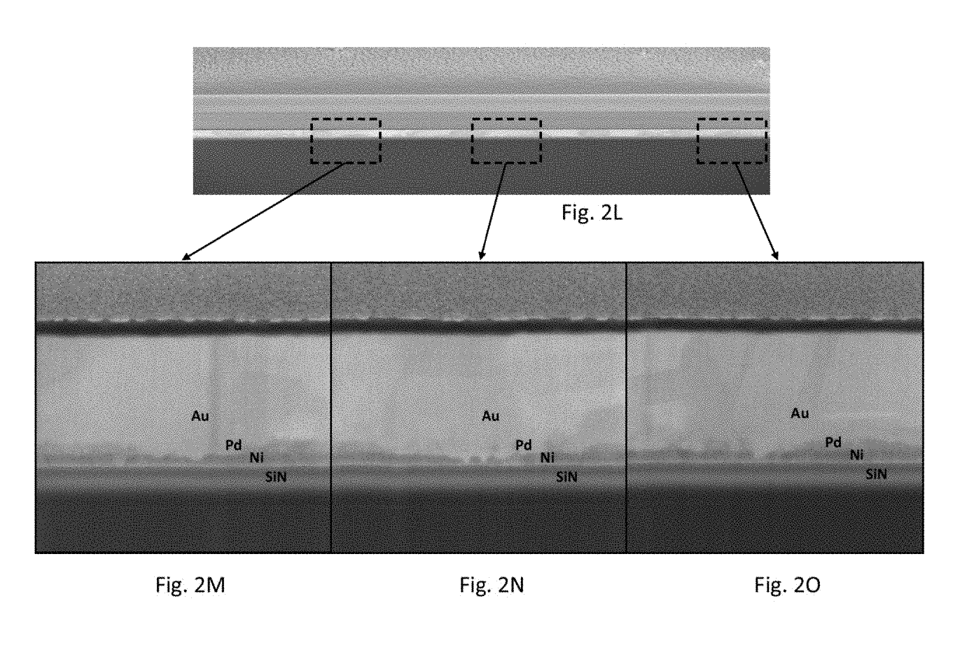

Please refer to FIG. 1A, which is the sectional schematic view of an embodiment of an improved gate metal structure for compound semiconductor devices of the present invention. The structure comprises a compound semiconductor substrate 10, a Schottky barrier layer 11, a gate metal 12, a drain electrode 13, a source electrode 14 and an insulating layer 15. The compound semiconductor substrate 10 is made of one material selected from the group consisting of GaAs, sapphire, InP, GaP, SiC and GaN. In current embodiment, the Schottky barrier layer 11 includes a GaN sub-layer 110 and an AlGaN sub-layer 111. The GaN sub-layer 110 is formed on the compound semiconductor substrate 10; the AlGaN sub-layer 111 is formed on the GaN sub-layer 110. The insulating layer 15 is formed on the AlGaN sub-layer 111. The insulating layer 15 is made of silicon nitride. The insulating layer 15 has a gate recess. The surrounding and the bottom of the gate recess are defined by the insulating layer 15 and the AlGaN sub-layer 111 respectively. The gate metal 12 is formed on the insulating layer 15 and covers the gate recess such that the gate metal 12 is contacted with the AlGaN sub-layer 111 at the bottom of the gate recess to form the Schottky contact. The drain electrode 13 and the source electrode 14 are formed respectively at the left and the right sides of the gate metal 12 on the AlGaN sub-layer 111. And the drain electrode 13 and the source electrode 14 form the ohmic contact with the AlGaN sub-layer 111 respectively. Please also refer to FIG. 1B which is the partial enlarged sectional schematic view of the gate electrode structure of an embodiment of an improved gate metal structure for compound semiconductor devices of the present invention. In the embodiment of the present invention, the gate metal 12 comprises a contact layer 120, a first diffusion barrier layer 121, a second diffusion barrier layer 122 and a conduct layer 123. The contact layer 120 is formed on the insulating layer 15 and covers the gate recess such that the contact layer 120 is contacted with the Schottky barrier layer 11 at the bottom of the gate recess to form the Schottky contact. In current embodiment, the contact layer 120 is contacted with the AlGaN sub-layer 111 at the bottom of the gate recess to form the Schottky contact. The first diffusion barrier layer 121 is formed on the contact layer 120. The second diffusion barrier layer 122 is formed on the first diffusion barrier layer 121. The conduct layer 123 is formed on the second diffusion barrier layer 122. In current embodiment, compound semiconductor substrate 10 is made of SiC; the insulating layer 15 is made of silicon nitride; the contact layer 120 is made of Ni; the first diffusion barrier layer 121 is made of Pd; the second diffusion barrier layer 122 is made of Pt; and the conduct layer 123 is made of Au. Thus, the gate metal 12 is formed by Ni, Pd, Pt and Au four metal layers. Applicant further observes from the phase diagram of the Pt—Pd binary alloy; Pt and Pd have excellent miscibility at 300° C. (or less). Hence, at 300° C. (or less), the integrity of the interface between Pt metal layer and Pd metal layer may be preserved; therefore, the cracks and peeling on the interface may be prevented. From the phase diagram of the Pd—Ni binary alloy, Pd and Ni have excellent miscibility at 300° C. (or less). Hence, at 300° C. (or less), the integrity of the interface between Pd metal layer and Ni metal layer may be preserved; therefore, the cracks and peeling on the interface may be prevented. Furthermore, from the phase diagram of the Au—Pt binary alloy, Au and Pt have excellent miscibility at 300° C. (or less). Hence, at 300° C. (or less), the integrity of the interface between Au metal layer and Pt metal layer may be preserved; therefore, the cracks and peeling on the interface may be prevented. Thus, the design of the gate metal 12 formed by Ni, Pd, Pt and Au four metal layers may preserve all of the integrity of the interface between Ni—Pd, the integrity of the interface between Pd—Pt, and the integrity of the interface between Pt—Au, so as to preserve the integrity of the gate metal 12, prevent the cracks and peeling, and enhance the reliability of the compound semiconductor devices.

In an embodiment, the thickness of the contact layer 120 may be greater than or equal to 10 Å and smaller than or equal to 500 Å, greater than 30 Å and smaller than 500 Å, greater than 50 Å and smaller than 500 Å, greater than 80 Å and smaller than 500 Å, greater than 100 Å and smaller than 500 Å, greater than 150 Å and smaller than 500 Å, greater than 200 Å and smaller than 500 Å, greater than 10 Å and smaller than 450 Å, greater than 10 Å and smaller than 400 Å, greater than 10 Å and smaller than 350 Å, greater than 30 Å and smaller than 450 Å, greater than 30 Å and smaller than 400 Å, greater than 30 Å and smaller than 350 Å, greater than 50 Å and smaller than 450 Å, greater than 50 Å and smaller than 400 Å, greater than 50 Å and smaller than 350 Å, greater than 80 Å and smaller than 450 Å, greater than 80 Å and smaller than 400 Å, greater than 80 Å and smaller than 350 Å, greater than 100 Å and smaller than 450 Å, greater than 100 Å and smaller than 400 Å, greater than 100 Å and smaller than 350 Å, greater than 150 Å and smaller than 450 Å, greater than 150 Å and smaller than 400 Å, greater than 150 Å and smaller than 350 Å, greater than 200 Å and smaller than 450 Å, or greater than 200 Å and smaller than 400 Å.

In an embodiment, the thickness of the first diffusion barrier layer 121 may be greater than or equal to 10 Å and smaller than or equal to 500 Å, greater than 30 Å and smaller than 500 Å, greater than 50 Å and smaller than 500 Å, greater than 80 Å and smaller than 500 Å, greater than 100 Å and smaller than 500 Å, greater than 150 Å and smaller than 500 Å, greater than 200 Å and smaller than 500 Å, greater than 10 Å and smaller than 450 Å, greater than 10 Å and smaller than 400 Å, greater than 10 Å and smaller than 350 Å, greater than 30 Å and smaller than 450 Å, greater than 30 Å and smaller than 400 Å, greater than 30 Å and smaller than 350 Å, greater than 50 Å and smaller than 450 Å, greater than 50 Å and smaller than 400 Å, greater than 50 Å and smaller than 350 Å, greater than 80 Å and smaller than 450 Å, greater than 80 Å and smaller than 400 Å, greater than 80 Å and smaller than 350 Å, greater than 100 Å and smaller than 450 Å, greater than 100 Å and smaller than 400 Å, greater than 100 Å and smaller than 350 Å, greater than 150 Å and smaller than 450 Å, greater than 150 Å and smaller than 400 Å, greater than 150 Å and smaller than 350 Å, greater than 200 Å and smaller than 450 Å, or greater than 200 Å and smaller than 400 Å.

In an embodiment, the thickness of the second diffusion barrier layer 122 may be greater than or equal to 10 Å and smaller than or equal to 500 Å, greater than 30 Å and smaller than 500 Å, greater than 50 Å and smaller than 500 Å, greater than 80 Å and smaller than 500 Å, greater than 100 Å and smaller than 500 Å, greater than 150 Å and smaller than 500 Å, greater than 200 Å and smaller than 500 Å, greater than 10 Å and smaller than 450 Å, greater than 10 Å and smaller than 400 Å, greater than 10 Å and smaller than 350 Å, greater than 30 Å and smaller than 450 Å, greater than 30 Å and smaller than 400 Å, greater than 30 Å and smaller than 350 Å, greater than 50 Å and smaller than 450 Å, greater than 50 Å and smaller than 400 Å, greater than 50 Å and smaller than 350 Å, greater than 80 Å and smaller than 450 Å, greater than 80 Å and smaller than 400 Å, greater than 80 Å and smaller than 350 Å, greater than 100 Å and smaller than 450 Å, greater than 100 Å and smaller than 400 Å, greater than 100 Å and smaller than 350 Å, greater than 150 Å and smaller than 450 Å, greater than 150 Å and smaller than 400 Å, greater than 150 Å and smaller than 350 Å, greater than 200 Å and smaller than 450 Å, or greater than 200 Å and smaller than 400 Å.

In an embodiment, the thickness of the conduct layer 123 may be greater than or equal to 50 Å and smaller than or equal to 6000 Å, greater than 100 Å and smaller than 6000 Å, greater than 150 Å and smaller than 6000 Å, greater than 200 Å and smaller than 6000 Å, greater than 300 Å and smaller than 6000 Å, greater than 400 Å and smaller than 6000 Å, greater than 500 Å and smaller than 6000 Å, greater than 50 Å and smaller than 5500 Å, greater than 50 Å and smaller than 5000 Å, greater than 50 Å and smaller than 4500 Å, greater than 50 Å and smaller than 4000 Å, greater than 100 Å and smaller than 5500 Å, greater than 100 Å and smaller than 5000 Å, greater than 100 Å and smaller than 4500 Å, greater than 100 Å and smaller than 4000 Å, greater than 150 Å and smaller than 5500 Å, greater than 150 Å and smaller than 5000 Å, greater than 150 Å and smaller than 4500 Å, greater than 150 Å and smaller than 4000 Å, greater than 200 Å and smaller than 5500 Å, greater than 200 Å and smaller than 5000 Å, greater than 200 Å and smaller than 4500 Å, greater than 200 Å and smaller than 4000 Å, greater than 300 Å and smaller than 5500 Å, greater than 300 Å and smaller than 5000 Å, greater than 300 Å and smaller than 4500 Å, greater than 300 Å and smaller than 4000 Å, greater than 400 Å and smaller than 5500 Å, greater than 400 Å and smaller than 5000 Å, greater than 400 Å and smaller than 4500 Å, greater than 400 Å and smaller than 4000 Å, greater than 500 Å and smaller than 5500 Å, greater than 500 Å and smaller than 5000 Å, greater than 500 Å and smaller than 4500 Å, or greater than 500 Å and smaller than 4000 Å.

Please refer to FIG. 1C which is the partial enlarged sectional schematic view of the gate electrode structure of another embodiment of an improved gate metal structure for compound semiconductor devices of the present invention. The structure of the gate metal 12 is mostly similar to the structure of the embodiment shown in FIG. 1B, except that it further comprises a protection layer 124 formed on the conduct layer 123 of the gate metal 12. The protection layer 124 is made of Ti.

All of the 22 samples of an improved gate metal structure for compound semiconductor devices of the present invention passed the reliability test at 300° C. for 6 hours. Applicant analyzes these samples of devices which have passed the reliability test at 300° C. for 6 hours. Please refer to FIG. 1D˜FIG. 1G, wherein FIG. 1D is the SEM image of an improved gate metal structure for compound semiconductor devices of the present invention after the reliability test at 300° C. for 6 hours; FIG. 1E˜FIG. 1G are the partial enlarged views of FIG. 1D respectively. The embodiment of FIG. 1A (the gate metal 12 structure formed by Ni, Pd, Pt and Au four metal layers, as shown in FIG. 1B) of an AlGaN/GaN high electron mobility transistor of the present invention after passed the reliability test at 300° C. for 6 hours. Since at 300° C. (or less), Ni and Pd have excellent miscibility, Pd and Pt have excellent miscibility, and Pt and Au have excellent miscibility, therefore, after the reliability test at 300° C. for 6 hours, the integrity of the gate metal 12 of the current embodiment may be preserved, the cracks and peeling on the interface may be prevented, and the reliability of the compound semiconductor devices may be enhanced.

Please also refer to FIG. 1H˜FIG. 1M, which are respectively the measurement results of the normalized drain saturation current at zero gate voltage (Idss), the normalized zero bias threshold voltage (Vto) and the normalized ON-Resistance (Ron) of an improved gate metal structure for compound semiconductor devices of the present invention after the reliability test at 110° C. for 500 hours. After the 22 samples of devices passed the reliability test at 110° C. for 500 hours under applying the voltage of 28V between the drain electrode and the source electrode, the measurement results of the normalized drain saturation current at zero gate voltage (Idss), the normalized zero bias threshold voltage (Vto), and the normalized ON-Resistance (Ron) are as shown in the Figures. The results show that the improved gate metal structure for compound semiconductor devices of the present invention after the reliability test at 110° C. for 500 hours under applying the voltage of 28V between the drain electrode and the source electrode, the characteristics vary only a little bit and may fulfill the standard of the reliability test.

In other embodiment, the second diffusion barrier layer 122 may be made of at least one material selected from the group consisting of Rh, Ta, Hf, Zr and Nb. Rh, Ta, Hf, Zr or Nb may be substituted for Pt as the material of the second diffusion barrier layer 122 and may also play the same effect.

In the embodiments of the present invention, the material of the second diffusion barrier layer 122 is non-oxidized. The material of the second diffusion barrier layer 122 may not be the metal oxide; otherwise the ON-Resistance will be raised too high such that the characteristics of the device will be varied significantly.

In other embodiments, the Schottky barrier layer 11 may also be composed of other epitaxial structure having a Schottky barrier.

As disclosed in the above description and attached drawings, the present invention can provide an improved gate metal structure for compound semiconductor devices. It is new and can be put into industrial use.

Although the embodiments of the present invention have been described in detail, many modifications and variations may be made by those skilled in the art from the teachings disclosed hereinabove. Therefore, it should be understood that any modification and variation equivalent to the spirit of the present invention be regarded to fall into the scope defined by the appended claims.

1. An improved gate metal structure for compound semiconductor devices comprising:
a compound semiconductor substrate;
a Schottky barrier layer formed on said compound semiconductor substrate;
an insulating layer formed on said Schottky barrier layer, wherein said insulating layer has a gate recess, and said gate recess has a surrounding and a bottom defined by said insulating layer and said Schottky barrier layer respectively; and
a gate metal including a contact layer, a first diffusion barrier layer, a second diffusion barrier layer and a conduct layer, wherein said contact layer is formed on said insulating layer and covers said gate recess, and said contact layer contacts with said Schottky barrier layer at the bottom of said gate recess, said first diffusion barrier layer is formed on said contact layer, said second diffusion barrier layer is formed on said first diffusion barrier layer, said conduct layer is formed on the second diffusion barrier layer, wherein said contact layer is made of Ni, wherein said first diffusion barrier layer is made of Pd, wherein said second diffusion barrier layer is made of Pt, wherein said conduct layer is made of Au, thereby the reliability of said compound semiconductor devices is enhanced.

2. (canceled)

3. The improved gate metal structure for compound semiconductor devices according to claim 1, wherein the material of said second diffusion barrier layer is non-oxidized.

4-7. (Canceled)

8. The improved gate metal structure for compound semiconductor devices according to claim 1, wherein a thickness of said second diffusion barrier layer is greater than or equal to 10 Å and smaller than 500 Å.

9. (canceled)

10. The improved gate metal structure for compound semiconductor devices according to claim 1, wherein a thickness of said first diffusion barrier layer is greater than or equal to 10 Å and smaller than 500 Å.

11. (canceled)

12. The improved gate metal structure for compound semiconductor devices according to claim 1, wherein a thickness of said contact layer is greater than or equal to 10 Å and smaller than 500 Å.

13. (canceled)

14. The improved gate metal structure for compound semiconductor devices according to claim 1, wherein a thickness of said conduct layer is greater than or equal to 50 Å and smaller than 6000 Å.

15. The improved gate metal structure for compound semiconductor devices according to claim 1, wherein said insulating layer is made of silicon nitride.

16. The improved gate metal structure for compound semiconductor devices according to claim 1, wherein said compound semiconductor substrate is made of one material selected from the group consisting of GaAs, sapphire, InP, GaP, SiC and GaN.

17. The improved gate metal structure for compound semiconductor devices according to claim 1, further comprising a protection layer formed on said conduct layer of said gate metal, wherein said protection layer is made of Ti.

18. (canceled)

19. The improved gate metal structure for compound semiconductor devices according to claim 1, wherein said Schottky barrier layer includes a GaN sub-layer and an AlGaN sub-layer, said GaN sub-layer is formed on said compound semiconductor substrate, said AlGaN sub-layer is formed on said GaN sub-layer.

20. (canceled)

21. An improved gate metal structure for compound semiconductor devices comprising:
a compound semiconductor substrate;
a Schottky barrier layer formed on said compound semiconductor substrate;
an insulating layer formed on said Schottky barrier layer, wherein said insulating layer has a gate recess, and said gate recess has a surrounding and a bottom defined by said insulating layer and said Schottky barrier layer respectively; and
a gate metal including a contact layer, a first diffusion barrier layer, a second diffusion barrier layer and a conduct layer, wherein said contact layer is formed on said insulating layer and covers said gate recess, and said contact layer contacts with said Schottky barrier layer at the bottom of said gate recess, said first diffusion barrier layer is formed on said contact layer, said second diffusion barrier layer is formed on said first diffusion barrier layer, said conduct layer is formed on the second diffusion barrier layer, wherein said contact layer is made of Ni, wherein said first diffusion barrier layer is made of Pd, wherein said second diffusion barrier layer is made of Rh, Ta, Hf, Zr and Nb, wherein said conduct layer is made of Au, thereby the reliability of said compound semiconductor devices is enhanced.

22. The improved gate metal structure for compound semiconductor devices according to claim 21, wherein the material of said second diffusion barrier layer is non-oxidized.

23. The improved gate metal structure for compound semiconductor devices according to claim 21, wherein a thickness of said second diffusion barrier layer is greater than or equal to 10 Å and smaller than 500 Å.

24. The improved gate metal structure for compound semiconductor devices according to claim 21, wherein a thickness of said first diffusion barrier layer is greater than or equal to 10 Å and smaller than 500 Å.

25. The improved gate metal structure for compound semiconductor devices according to claim 21, wherein a thickness of said contact layer is greater than or equal to 10 Å and smaller than 500 Å.

26. The improved gate metal structure for compound semiconductor devices according to claim 11, wherein a thickness of said conduct layer is greater than or equal to 50 Å and smaller than 6000 Å.

27. The improved gate metal structure for compound semiconductor devices according to claim 21, wherein said insulating layer is made of silicon nitride.

28. The improved gate metal structure for compound semiconductor devices according to claim 21, wherein said compound semiconductor substrate is made of one material selected from the group consisting of GaAs, sapphire, InP, GaP, SiC and GaN.

29. The improved gate metal structure for compound semiconductor devices according to claim 21, further comprising a protection layer formed on said conduct layer of said gate metal, wherein said protection layer is made of Ti.

30. The improved gate metal structure for compound semiconductor devices according to claim 21, wherein said Schottky barrier layer includes a GaN sub-layer and an AlGaN sub-layer, said GaN sub-layer is formed on said compound semiconductor substrate, said AlGaN sub-layer is formed on said GaN sub-layer.
